(19) United States
(12) Patent Application Publication
(10) Pub. No.: US 2010/0289133 A1
(43) Pub. Date: Nov. 18, 2010

(54) Stackable Package Having Embedded Interposer and Method for Making the Same

(76) Inventors: Shin-Hua Chao, Kaohsiung (TW); Teck-Chong Lee, Kaohsiung (TW); Shing-Cheng Liang, Kaohsiung (TW)

Correspondence Address: MCCRACKEN & FRANK LLP, 311 S. WACKER DRIVE, SUITE 2500, CHICAGO, IL, 60606, US

(21) Appl. No.: 12/727,770

(22) Filed: Mar. 19, 2010

(30) Foreign Application Priority Data
May 18, 2009 (TW) 098116424

(51) Int. Cl. H01L 23/488; H01L 21/60; H01L 23/498

(52) U.S. Cl. 257/692; 438/108; 257/778; 257/E21.511; 257/E23.023; 257/E23.06

(57) ABSTRACT

The present invention relates to a stackable package having an embedded interposer and a method for making the same. The package includes a substrate, a chip, a first embedded interposer, a circuit layer and a solder mask. The substrate has an upper surface, a bottom surface and at least one connecting pad. The connecting pad is disposed adjacent to the upper surface. The chip is disposed adjacent to the upper surface of the substrate, and is electrically connected to the substrate. The first embedded interposer encapsulates the upper surface of the substrate and the chip. The to first embedded interposer includes at least one plating through hole. The plating through hole penetrates through the first embedded interposer, and is connected to the connecting pad of the substrate. The circuit layer is disposed adjacent to the first embedded interposer, and the plating through hole is connected to the circuit layer. The circuit layer includes at least one pad. The solder mask is disposed adjacent to the circuit layer, and exposes the pad. Therefore, the package has more pads for inputting/outputting, more flexibility for stacking a top package, and a reduced total thickness.

### BACKGROUND OF THE INVENTION

1. Field of the Invention

The present invention relates to a stackable package and a method for making the same, and more particularly to a stackable package having an embedded interposer and a method for making the same.

2. Description of the Related Art

FIG. 1 shows a cross-sectional view of a first conventional stackable package. The first conventional stackable package 1 comprises a substrate 11, a chip 12, a plurality of wires 13, a molding compound 14 and a plurality of solder balls 15. The substrate 11 comprises a first surface 111, a second surface 112, a plurality of through vias 113 and a plurality of input/output pads 114. The through vias 113 penetrate through the substrate 11. The input/output pads 114 are disposed at the periphery of the first surface 111 of the substrate 11, and are exposed to the first surface 111. The chip 12 is disposed on the first surface 111 of the substrate 11. The wires 13 electrically connect the substrate 11 and the chip 12. The molding compound 14 encapsulates part of the substrate 11, the chip 12 and the wires 13. The solder balls 15 are disposed on the second surface 112 of the substrate 11.

The first conventional stackable package 1 has the following disadvantages. The chip 12 and the molding compound 14 occupy most of the first surface 111 of the substrate 11, and the input/output pads 114 are disposed at the periphery of the first surface 111 of the substrate 11. Therefore, the number and distribution of the input/output pads 114 are limited by a small usable area, and another package which needs more input/output pads cannot be stacked on the top of the first conventional stackable package 1.

FIG. 2 shows a cross-sectional view of a second conventional stackable package. The second conventional stackable package 2 comprises a first substrate 21, a first chip 22, an underfill 23, a dielectric layer 24, a second substrate 25, a plurality of wires 26, a molding compound 27 and a plurality of solder balls 28. The first substrate 21 has a first surface 211 and a second surface 212. The first chip 22 is disposed on the first substrate 21, and comprises a plurality of first bumps 221. The underfill 23 encapsulates the first bumps 221 of the first chip 22. The dielectric layer 24 is disposed on the first chip 22. The second substrate 25 is disposed on the dielectric layer 24, and comprises a first surface 251, a second surface 252 and a plurality of input/output pads 253. The first surface 251 contacts the dielectric layer 24. The input/output pads 253 are disposed on the second surface 252. The wires 26 electrically connect the second substrate 25 and the first substrate 21. The molding compound 27 encapsulates the first surface 211 of the first substrate 21, the first chip 22, the dielectric layer 24, the first surface 251 of the second substrate 25 and the wires 26, and exposes the input/output pads 253 of the second substrate 25. The solder balls 28 are disposed on the second surface 212 of the first substrate 21.

The second conventional stackable package 2 has the following disadvantages. Even though a top package having full matrix ball out can be stacked on the top of the package 2, a dielectric layer 24 has to be disposed between the first chip 22 and the second substrate 25, so the thickness of the package 2 is increased and the manufacturing cost is increased.

Therefore, it is necessary to provide a stackable package having an embedded interposer and a method for making the same to solve the above problems.

### SUMMARY OF THE INVENTION

The present invention is directed to a stackable package having an embedded interposer. The package comprises a substrate, a chip, a first embedded interposer, a circuit layer and a solder mask. The substrate has an upper surface, a bottom surface and at least one connecting pad. The connecting pad is disposed adjacent to the upper surface. The chip is disposed adjacent to the upper surface of the substrate, and is electrically connected to the substrate. The first embedded interposer encapsulates the upper surface of the substrate and the chip, and comprises at least one plating through hole. The plating through hole penetrates through the first embedded interposer, and is connected to the connecting pad of the substrate. The circuit layer is disposed adjacent to the first embedded interposer, the plating through hole is connected to the circuit layer, and the circuit layer comprises at least one pad. The solder mask is disposed adjacent to the circuit layer and exposes the pad.

The present invention is further directed to a method for making a stackable package having an embedded interposer. The method comprises the following steps: (a) providing a substrate having an upper surface, a bottom surface and at least one connecting pad, the connecting pad being disposed adjacent to the upper surface; (b) disposing a chip adjacent to the upper surface of the substrate, the chip being electrically connected to the substrate; (c) providing a first embedded interposer being disposed adjacent to the substrate; (d) pressing the first embedded interposer, so that the first embedded interposer encapsulates the upper surface of the substrate and the chip; (e) forming at least one plating through hole in the first embedded interposer, the plating through hole penetrating through the first embedded interposer and being connected to the connecting pad of the substrate; (f) forming a circuit layer on the first embedded interposer, the plating through hole being connected to the circuit layer, and the circuit layer comprising at least one pad; (g) forming a solder mask on the circuit layer, the solder mask exposing the pad; and (h) forming a plurality of solder balls on the bottom surface of the substrate.

The present invention is further directed to a method for making a stackable package having an embedded interposer. The method comprises the following steps: (a) providing a package having an embedded interposer, the package comprising a substrate, a chip, a first embedded interposer and a metal layer, the substrate having an upper surface, a bottom surface and at least one connecting pad, the connecting pad being exposed to the upper surface, the chip being disposed adjacent to the upper surface of the substrate, the chip being electrically connected to the substrate, the first embedded interposer encapsulating the upper surface of the substrate and the chip, and the metal layer being disposed adjacent to the first embedded interposer; (b) forming at least one plating through hole in the first embedded interposer, the plating through hole penetrating through the first embedded interposer and being connected to the connecting pad of the substrate; (c) removing part of the metal layer, so as to form a circuit layer on the first embedded interposer, the plating through hole being connected to the circuit layer, the circuit layer comprising at least one pad; (d) forming a solder mask on the circuit layer, the solder mask exposing the pad; and (e) forming a plurality of solder balls on the bottom surface of the substrate.

The plating through hole and the circuit layer enable the package to have more input/output pads, and a dielectric layer may be omitted so as to reduce the total thickness of the package. Moreover, the underfill or the molding compound of the conventional stackable package 1, 2 are replaced with the first embedded interposer, so as to reduce the manufacturing steps and manufacturing cost. Furthermore, the method of the present invention can be conducted on a large substrate, so as to improve the production capacity.

### BRIEF DESCRIPTION OF THE DRAWINGS

FIG. 1 is a cross-sectional view of a first conventional stackable package;

FIG. 2 is a cross-sectional view of a second conventional stackable package;

FIGS. 3 to 15 are schematic views of a method for making a stackable package having an embedded interposer according to the present invention;

FIG. 16 is a schematic view of a stackable package having an embedded interposer according to a first embodiment of the present invention with another package stacked thereon;

FIG. 17 is a cross-sectional view of a stackable package having an embedded interposer according to a second embodiment of the present invention; and

FIG. 18 is a cross-sectional view of a stackable package having an embedded interposer according to a third embodiment of the present invention.

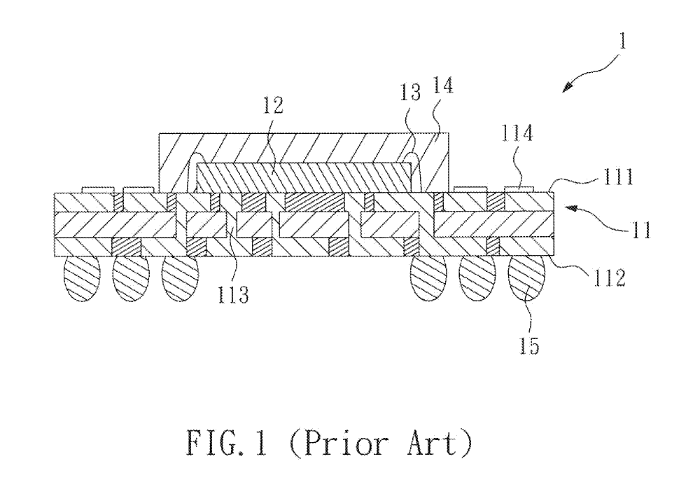

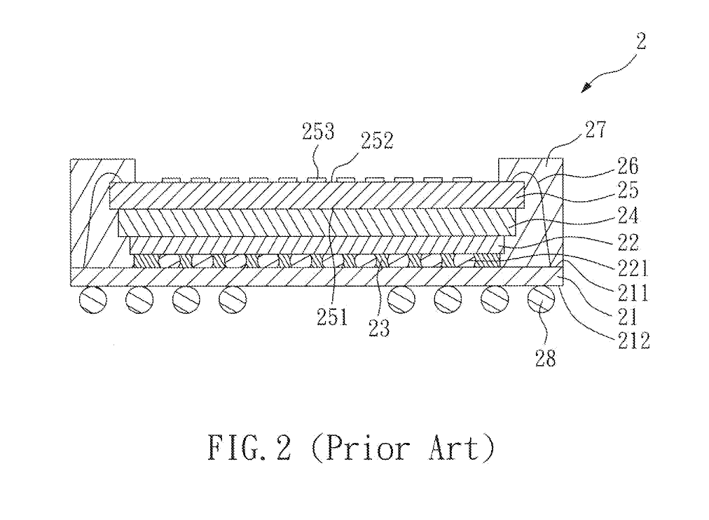

### DETAILED DESCRIPTION OF THE INVENTION

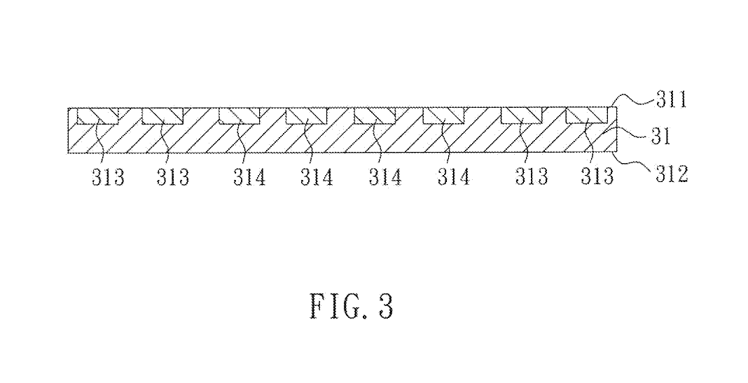

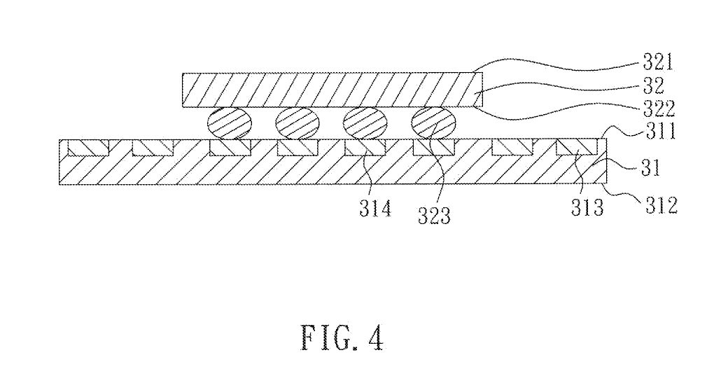

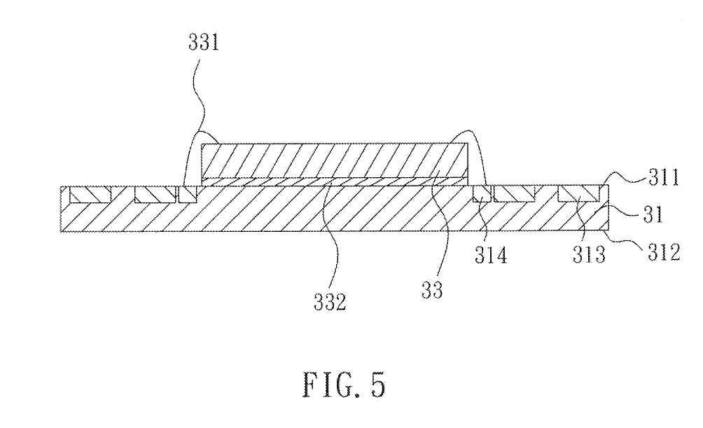

FIGS. 3 to 15 show schematic views of a method for making a stackable package having an embedded interposer according to the present invention. As shown in FIG. 3, a substrate 31 is provided. The substrate 31 has an upper surface 311, a bottom surface 312, at least one connecting pad 313 and at least one substrate pad 314. The connecting pad 313 and the substrate pad 314 are disposed adjacent to the upper surface 311. As shown in FIG. 4, a chip is disposed adjacent to the upper surface 311 of the substrate 31. The chip is electrically connected to the substrate 31. In the embodiment, the chip is a flip chip 32, which comprises an upper surface 321, a bottom surface 322 and a plurality of bumps 323, the bumps 323 are disposed adjacent to the bottom surface 322. The flip chip 32 is electrically connected to the substrate pad 314 of the substrate 31 by the bumps 323. However, the chip may be a wire-bonded chip 33, which is electrically connected to the substrate pad 314 of the substrate 31 by a plurality of wires 331, and adhered to the substrate 31 by an adhesive 332, as shown in FIG. 5.

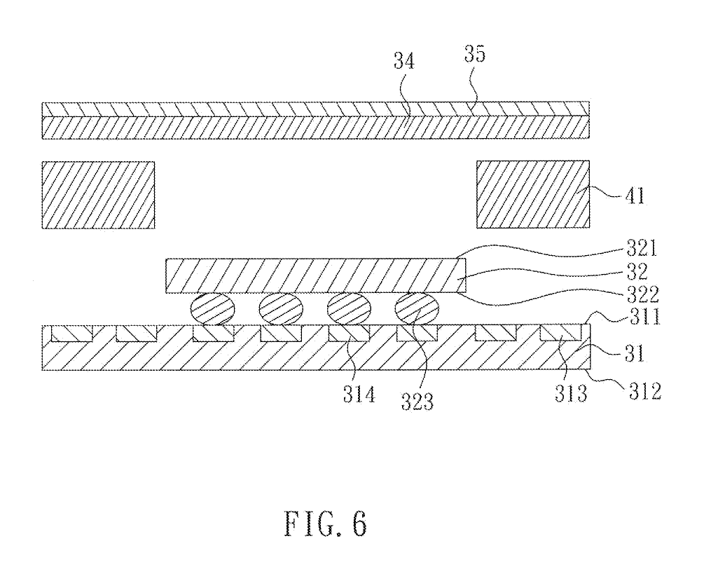

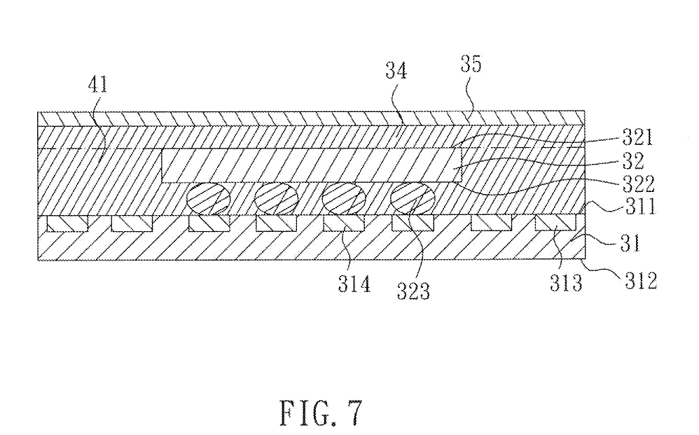

As shown in FIG. 6, a first embedded interposer 34 is provided. The first embedded interposer 34 is disposed adjacent to the substrate 31. In the embodiment, a metal layer 35 and a second embedded interposer 41 are further provided. The metal layer 35 is disposed adjacent to the first embedded interposer 34. The second embedded interposer 41 is disposed between the first embedded interposer 34 and the substrate 31. As shown in FIG. 7, the first embedded interposer 34, the metal layer 35 and the second embedded interposer 41 are pressed, so that the first embedded interposer 34 and the second embedded interposer 41 encapsulate the upper surface 311 of the substrate 31 and the chip. Preferably, the material of the first embedded interposer 34 and the second embedded interposer 41 is ammonium bifluoride (ABF), bismaleimide (BT), polyimide (PI), liquid crystal polymer (LCP), FR4 or FR5. It is understood that, in the present invention, the second embedded interposer 41 may be omitted, and the first embedded interposer 34 is pressed directly. The material of the first embedded interposer 34 is the same as that of the second embedded interposer 41, and therefore the first embedded interposer 34 and the second embedded interposer 41 has high compatibility after pressing.

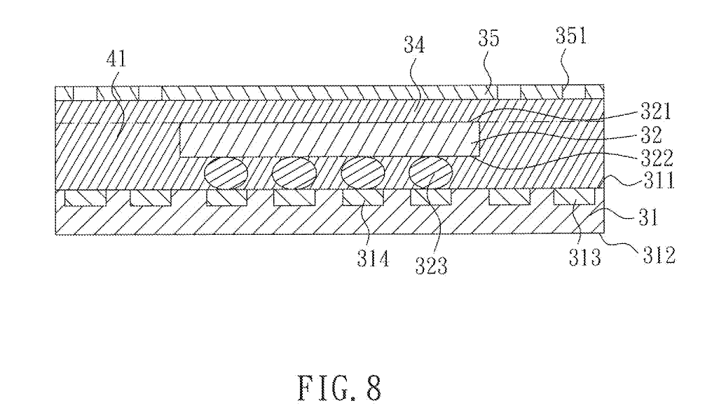

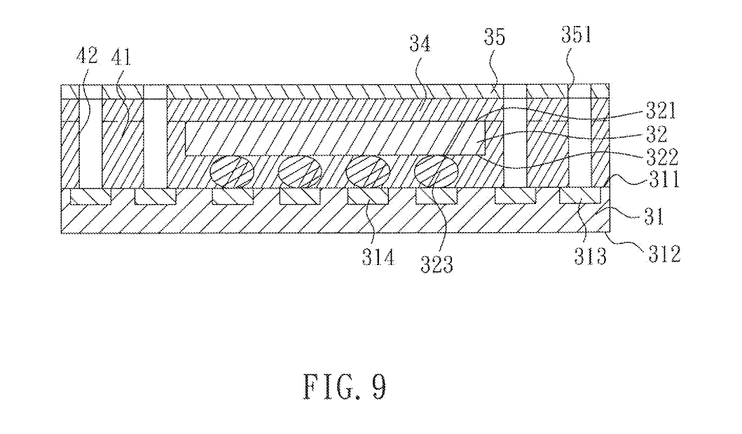

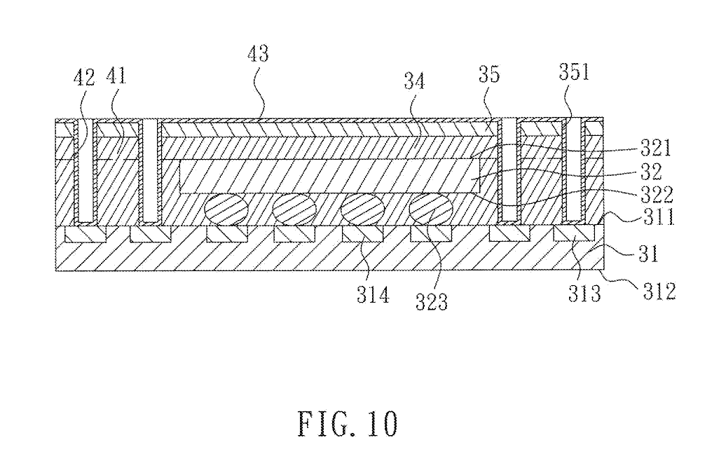

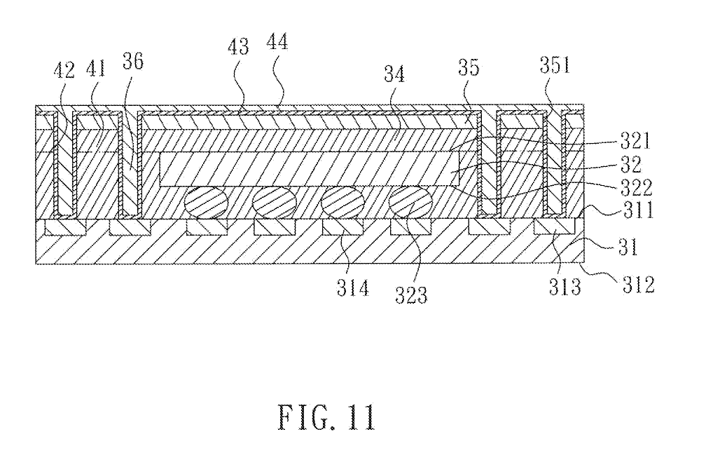

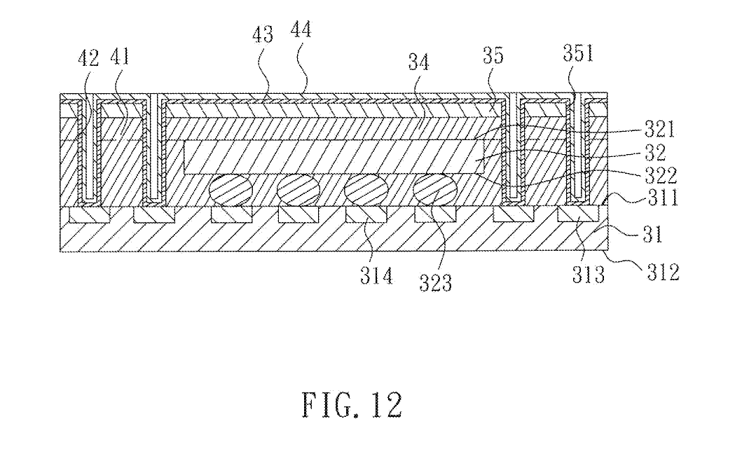

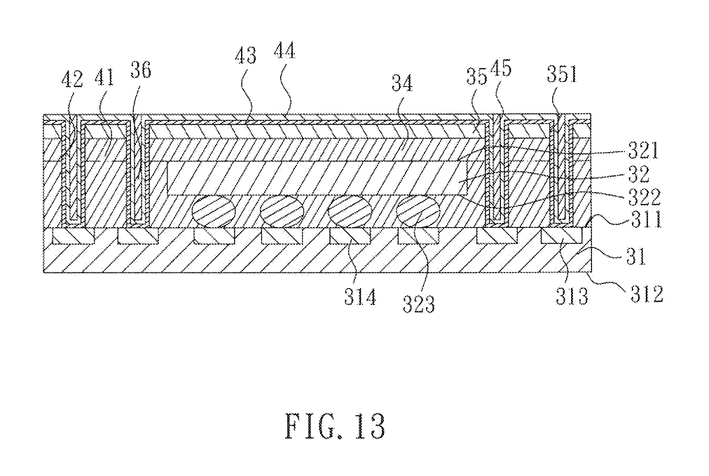

Then, at least one plating through hole 36 (FIG. 11) is formed in the first embedded interposer 34 and the second embedded interposer 41. The plating through hole 36 penetrates through the first embedded interposer 34 and the second embedded interposer 41, and is connected to the connecting pad 313 of the substrate 31. In the embodiment, the method for forming the plating through hole 36 comprises the following steps. As shown in FIG. 8, part of the metal layer 35 is removed, so as to form a plurality of openings 351 exposing part of the first embedded interposer 34. As shown in FIG. 9, part of the first embedded interposer 34 and part of the second embedded interposer 41 are removed by laser or other equivalent drilling method, so as to form a plurality of through holes 42 exposing the connecting pad 313 of the substrate 31. As shown in FIG. 10, a seed layer 43 is formed on the wall of the through holes 42. As shown in FIG. 11, a conductor layer 44 is formed on the seed layer 43, and fills up the through holes 42. However, in other applications, the conductor layer 44 does not fill up the through holes 42 (FIG. 12), and a conductive paste 45 is then formed on the conductor layer 44, and fills up the through holes 42 (FIG. 13).

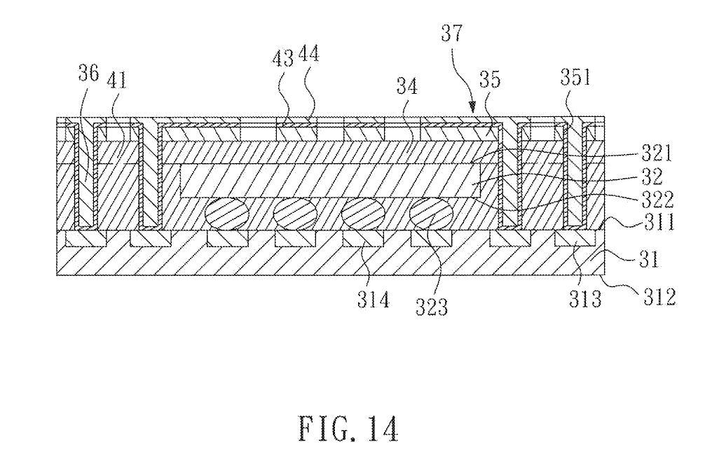

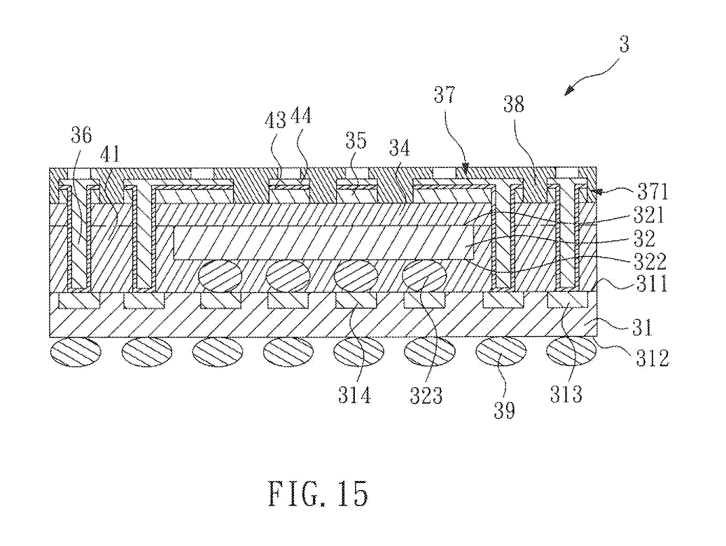

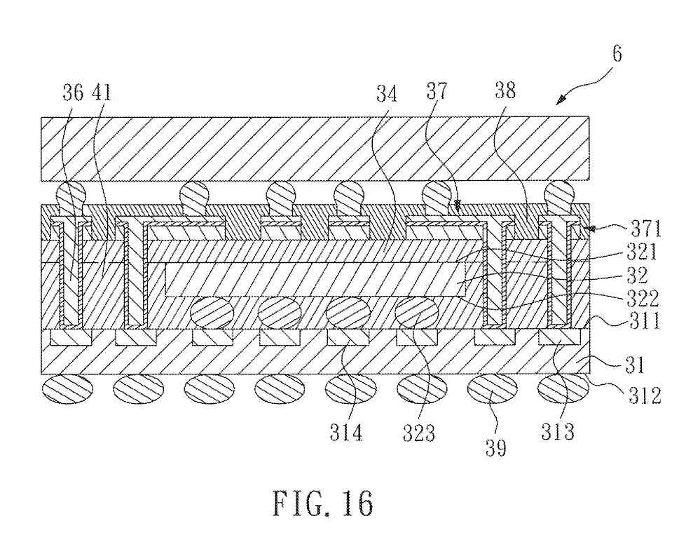

As shown in FIG. 14, a circuit layer 37 is formed on the first embedded interposer 34. The plating through hole 36 is connected to the circuit layer 37, and the circuit layer 37 comprises at least one pad 371. In the embodiment, part of the metal layer 35, part of the seed layer 43 and part of the conductor layer 44 are removed by exposing and developing procedure, so as to form the circuit layer 37. However, in other applications, the first embedded interposer 34 is provided, the metal layer 35 is omitted, and the first embedded interposer 34 is pressed directly. After the plating through hole 36 is formed, part of the seed layer 43 and part of the conductor layer 44 are removed, so as to form the circuit layer 37. As shown in FIG. 15, a solder mask 38 is formed on the circuit layer 37, and exposes the pad 371. In the embodiment, the method further comprises a step of conducting metal surface finish process. Then, a plurality of solder balls 39 are formed on the bottom surface 312 of the substrate 31. As shown in FIG. 16, in the embodiment, the method further comprises a step of stacking another package 6.

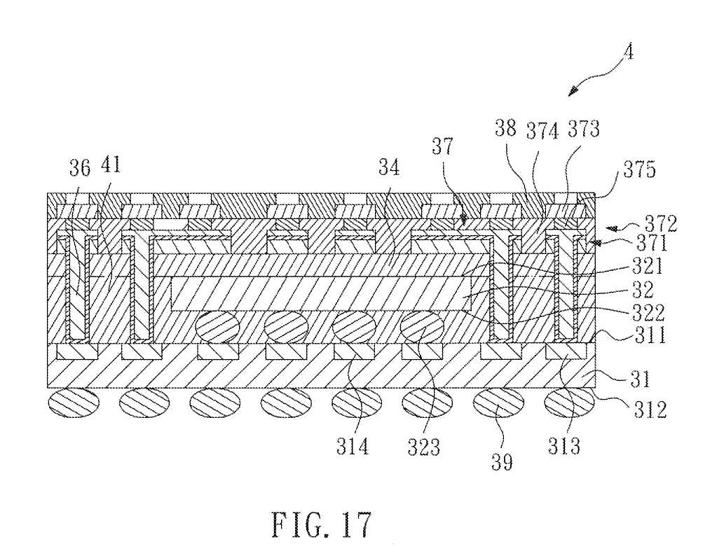

However, as shown in FIG. 17, in other applications, the circuit layer 37 further comprises a first circuit layer 372, a second circuit layer 373, a dielectric layer 374 and at least one conductive through hole 375. The first circuit layer 372 is formed on the first embedded interposer 34, the second circuit layer 373 is formed on the first circuit layer 372, the dielectric layer 374 is disposed between the first circuit layer 372 and the second circuit layer 373, and the conductive through hole 375 electrically connects the first circuit layer 372 and the second circuit layer 373.

FIG. 15 shows a cross-sectional view of a stackable package having an embedded interposer according to a first embodiment of the present invention. The stackable package 3 having an embedded interposer comprises a substrate 31, a chip, a first embedded interposer 34, a circuit layer 37, a solder mask 38, a plurality of solder balls 39 and a second embedded interposer 41. The substrate 31 has an upper surface 311, a bottom surface 312 and at least one connecting pad 313, and the connecting pad 313 is disposed adjacent to the upper surface 311. The chip is disposed adjacent to the upper surface 311 of the substrate 31, and is electrically connected to the substrate 31. In the embodiment, the chip is a flip chip 32, which comprises an upper surface 321, a bottom surface 322 and a plurality of bumps 323. The bumps 323 are disposed adjacent to the bottom surface 322, and the flip chip 32 is electrically connected to the substrate 31 by the bumps 323.

The first embedded interposer 34 and the second embedded interposer 41 encapsulate the upper surface 311 of the substrate 31 and the chip, and comprise at least one plating through hole 36 therein. The plating through hole 36 penetrates through the first embedded interposer 34 and the second embedded interposer 41, and is connected to the connecting pad 313 of the substrate 31. The circuit layer 37 is disposed adjacent to the first embedded interposer 34, and the plating through hole 36 is connected to the circuit layer 37. The circuit layer 37 comprises at least one pad 371. The solder mask 38 is disposed adjacent to the circuit layer 37, and exposes the pad 371. In the embodiment, the solder balls 39 are disposed adjacent to the bottom surface 312 of the substrate 31. The second embedded interposer 41 is disposed between the first embedded interposer 34 and the substrate 31.

FIG. 17 shows a cross-sectional view of a stackable package having an embedded interposer according to a second embodiment of the present invention. The package 4 according to the second embodiment is substantially the same as the package 3 (FIG. 15) according to the first embodiment, and the same elements are designated by the same reference numbers. The package 4 according to the second embodiment is different from the package 3 according to the first embodiment in the structure of the circuit layer 37. In the embodiment, the circuit layer 37 further comprises a first circuit layer 372, a second circuit layer 373, a dielectric layer 374 and at least one conductive through hole 375. The first circuit layer 372 is disposed adjacent to the first embedded interposer 34, the second circuit layer 373 is disposed adjacent to the first circuit layer 372, the dielectric layer 374 is disposed between the first circuit layer 372 and the second circuit layer 373, and the conductive through hole 375 electrically connects the first circuit layer 372 and the second circuit layer 373.

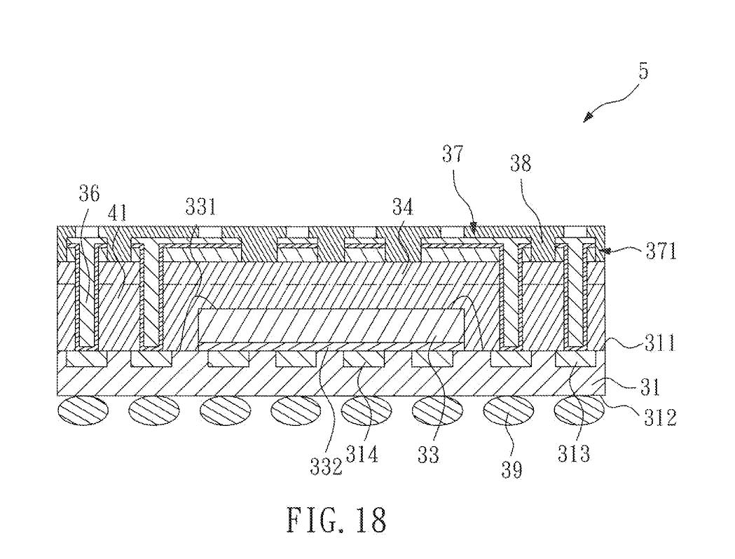

FIG. 18 shows a cross-sectional view of a stackable package having an embedded interposer according to a third embodiment of the present invention. The package 5 according to the third embodiment is substantially the same as the package 3 (FIG. 15) according to the first embodiment, and the same elements are designated by the same reference numbers. The package 5 according to the third embodiment is different from the package 3 according to the first embodiment in the structure of the chip. In the embodiment, the chip is a wire-bonded chip 33, which is electrically connected to the substrate 31 by a plurality of wires 331, and adhered to the substrate 31 by an adhesive 332.

The plating through hole 36 and the circuit layer 37 enable the packages 3, 4, 5 to have more input/output pads 371, and reduce the total thickness of the packages 3, 4, 5. Moreover, the underfill 23 or the molding compound 14, 27 of the conventional stackable package 1, 2 are replaced with the first embedded interposer 34, so as to reduce the manufacturing steps and manufacturing cost. Furthermore, the method of the present invention can be conducted on a large substrate, so as to improve the production capacity.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined by the appended claims.

What is claimed is:

1. A stackable package having an embedded interposer, comprising:
a substrate, having an upper surface, a bottom surface and at least one connecting pad, the connecting pad being disposed adjacent to the upper surface;
a chip, disposed adjacent to the upper surface of the substrate, the chip being electrically connected to the substrate;
a first embedded interposer, encapsulating the upper surface of the substrate and the chip and comprising at least one plating through hole, the plating through hole penetrating through the first embedded interposer and being connected to the connecting pad of the substrate;
a circuit layer, disposed adjacent to the first embedded interposer, the plating through hole being connected to the circuit layer, the circuit layer comprising at least one pad; and
a solder mask, disposed adjacent to the circuit layer and exposing the pad.

2. The package as claimed in claim 1, wherein the chip is a flip chip, which comprises an upper surface, a bottom surface and a plurality of bumps, the bumps are disposed adjacent to the bottom surface, and the flip chip is electrically connected to the substrate by the bumps.

3. The package as claimed in claim 1, wherein the chip is a wire-bonded chip, which is electrically connected to the substrate by a plurality of wires, and adhered to the substrate by an adhesive.

4. The package as claimed in claim 1, wherein the circuit layer comprises a first circuit layer, a second circuit layer and a dielectric layer, the first circuit layer is disposed adjacent to the first embedded interposer, the second circuit layer is disposed adjacent to the first circuit layer, and the dielectric layer is disposed between the first circuit layer and the second circuit layer.

5. The package as claimed in claim 4, wherein the circuit layer further comprises at least one conductive through hole electrically connecting the first circuit layer and the second circuit layer.

6. The package as claimed in claim 1, further comprising a second embedded interposer disposed between the first embedded interposer and the substrate.

7. The package as claimed in claim 1, further comprising a plurality of solder balls disposed adjacent to the bottom surface of the substrate.

8. A method for making a stackable package having an embedded interposer, comprising:
(a) providing a substrate having an upper surface, a bottom surface and at least one connecting pad, the connecting pad being disposed adjacent to the upper surface;
(b) disposing a chip adjacent to the upper surface of the substrate, the chip being electrically connected to the substrate;
(c) providing a first embedded interposer being disposed adjacent to the substrate;
(d) pressing the first embedded interposer, so that the first embedded interposer encapsulates the upper surface of the substrate and the chip;
(e) forming at least one plating through hole in the first embedded interposer, the plating through hole penetrating through the first embedded interposer and being connected to the connecting pad of the substrate;
(f) forming a circuit layer on the first embedded interposer, the plating through hole being connected to the circuit layer, and the circuit layer comprising at least one pad;
(g) forming a solder mask on the circuit layer, the solder mask exposing the pad; and
(h) forming a plurality of solder balls on the bottom surface of the substrate.

9. The method as claimed in claim 8, wherein the chip is a flip chip, which comprises an upper surface, a bottom surface and a plurality of bumps, the bumps are disposed adjacent to the bottom surface, and the flip chip is electrically connected to the substrate by the bumps in step (b).

10. The method as claimed in claim 8, wherein the chip is a wire-bonded chip, which is electrically connected to the substrate by a plurality of wires, and adhered to the substrate by an adhesive in step (b).

11. The method as claimed in claim 8, wherein a second embedded interposer disposed between the first embedded interposer and the substrate is further provided in step (c), and the first embedded interposer and the second embedded interposer are pressed in step (d).

12. The method as claimed in claim 8, wherein a metal layer is further provided in step (c), the first embedded interposer and the metal layer are pressed in step (d), and part of the metal layer is removed in step (f), so as to form the circuit layer.

13. The method as claimed in claim 12, wherein step (f) comprises:
(f1) removing part of the metal layer, so as to form a plurality of openings exposing part of the first embedded interposer;
(f2) removing part of the first embedded interposer by laser, so as to form a plurality of through holes exposing the connecting pads of the substrate;
(f3) forming a seed layer on the wall of the through holes; and
(f4) forming a conductor layer on the seed layer.

14. The method as claimed in claim 13, further comprising a step of forming a conductive paste on the conductor layer and filling the through holes after step (f4).

15. The method as claimed in claim 13, wherein the conductor layer fills up the through holes in step (f4).

16. The method as claimed in claim 8, wherein step (f) comprises:
(f1) forming a metal layer on the first embedded interposer; and
(f2) removing part of the metal layer, so as to form the circuit layer.

17. The method as claimed in claim 8, wherein the circuit layer comprises a first circuit layer, a second circuit layer and a dielectric layer, the first circuit layer is disposed adjacent to the first embedded interposer, the second circuit layer is disposed adjacent to the first circuit layer, and the dielectric layer is disposed between the first circuit layer and the second circuit layer in step (f).

18. A method for making a stackable package having an embedded interposer, comprising:
(a) providing a package having an embedded interposer, the package comprising a substrate, a chip, a first embedded interposer and a metal layer, the substrate having an upper surface, a bottom surface and at least one connecting pad, the connecting pad being exposed to the upper surface, the chip being disposed adjacent to the upper surface of the substrate, the chip being electrically connected to the substrate, the first embedded interposer encapsulating the upper surface of the substrate and the chip, and the metal layer being disposed adjacent to the first embedded interposer;
(b) forming at least one plating through hole in the first embedded interposer, the plating through hole penetrating through the first embedded interposer and being connected to the connecting pad of the substrate;
(c) removing part of the metal layer, so as to form a circuit layer on the first embedded interposer, the plating through hole being connected to the circuit layer, the circuit layer comprising at least one pad;
(d) forming a solder mask on the circuit layer, the solder mask exposing the pad; and
(e) forming a plurality of solder balls on the bottom surface of the substrate.

19. The method as claimed in claim 18, wherein the chip is a flip chip, which comprises an upper surface, a bottom surface and a plurality of bumps, the bumps are disposed adjacent to the bottom surface, and the flip chip is electrically connected to the substrate by the bumps in step (a).

20. The method as claimed in claim 18, wherein the chip is a wire-bonded chip, which is electrically connected to the substrate by a plurality of wires, and adhered to the substrate by an adhesive in step (a).
